(19) United States
(12) Patent Application Publication
(10) Pub. No.: US 2026/0213467 A1
(43) Pub. Date: Jul. 23, 2026

(54) CONNECTOR ASSEMBLY

(71) Applicant: Molex, LLC, Lisle, IL (US)

(72) Inventors: Ming-Huei Kao, New Taipei (TW); Kuan-Chih Huang, New Taipei (TW); Vivek Shah, Buffalo Grove, IL (US); Saiyed Muhammad Hasan Ali, Conway, AR (US); Hui-Hsuan Yang, New Taipei (TW); Kuan-Lin Peng, New Taipei (TW); Wei-Cheng Lin, New Taipei (TW)

(21) Appl. No.: 19/554,702

(22) Filed: Mar. 3, 2026

Related U.S. Application Data
(63) Continuation of application No. 18/098,728, filed on Jan. 19, 2023, now Pat. No. 12,592,522.
(60) Provisional application No. 63/304,280, filed on Jan. 28, 2022.

(30) Foreign Application Priority Data
Aug. 24, 2022 (CN) 202211021149.9

(51) Int. Cl. H01R 13/6583; H01R 13/508; H05K 7/20

(52) U.S. Cl. CPC H01R 13/6583; H01R 13/508; H05K 7/20418

(57) ABSTRACT

Connector assemblies and shield cage assemblies are described. An example shield cage assembly includes a guiding shield cage, a partitioning bracket provided in the guiding shield cage, and a movable heat sink assembled to the partitioning bracket. The guiding shield cage includes a limiting piece on a side wall, and the movable heat sink includes a limiting groove in a side wall. The movable heat sink is capable of moving relative to the partitioning bracket between a front position where the limiting piece is positioned at a rear end of the limiting groove and a rearward position where the limiting piece is positioned at a front end of the limiting groove.

### BACKGROUND

Chinese invention patent application publication No. CN106469878A (corresponding to U.S. Pat. No. 10,153,571B2) discloses a connector system, the connector system includes a cage and a biased heat sink. The cage includes an intermediate section, the intermediate section includes an upper wall and a lower wall, the upper wall and the lower wall help to define an upper port and a lower port in the cage, the lower wall includes a hole formed therein so that the intermediate section and the lower port are communicated with each other, the biased heat sink is arranged in the intermediate section between the upper port and the lower port, the biased heat sink extends through the hole and enters into the lower port. The cage disclosed in this prior art is positioned over a stacked connector, an opening formed to a bottom portion of the cage allows the stacked connector to be capable of being arranged inside the cage, a rear end of the intermediate section is necessary to extend to between an upper receptacle and a lower receptacle of the stacked connector. However, in an assembling case that the stacked connector needs to be mounted on a circuit board in advance, the intermediate section of the cage which is assembled later will interfere with the stacked connector, which makes the cage to be assembled later cannot be assembled.

Chinese utility model patent application issuance publication No. CN204257893U discloses a partitioning plate portion which is fixed in a metal shell and is positioned between two receiving cavities, the partitioning plate portion includes two partitioning plates which are respectively exposed into the two receiving cavities, the two partitioning plates interpose a metal heat dissipating block, the two partitioning plates are provided with heat dissipating holes which pass through the two partitioning plates respectively and are used to be respectively communicated with the two receiving cavities and the metal heat dissipating block, the metal heat dissipating block includes a main body portion which is used to attach with the two partitioning plates and a snapping protrusion which extends rearwardly from the main body portion and is inserted into and positioned to an insulative body. Although this prior art discloses the snapping protrusion which extends rearwardly from the metal heat dissipating block positioned in the partitioning plate portion and is inserted into and positioned to the insulative body of a connector, in an assembling case that the connector needs to be mounted on a circuit board in advance, the partitioning plate portion of the metal shell which is assembled later will interfere with the connector, which makes the metal shell to be assembled later cannot be assembled. In this case, although that the metal heat dissipating block is directly cut short may solve this assembling interference problem, heat dissipating efficacy will be relatively lowered.

### SUMMARY

Therefore, an object of the present disclosure is to provide a connector assembly which can improve at least one problem of the prior art.

Connector assemblies and shield cage assemblies are described. An example shield cage assembly includes a guiding shield cage, a partitioning bracket provided in the guiding shield cage, and a movable heat sink assembled to the partitioning bracket. The guiding shield cage includes a limiting piece on a side wall, and the movable heat sink includes a limiting groove in a side wall. The movable heat sink is capable of moving relative to the partitioning bracket between a front position where the limiting piece is positioned at a rear end of the limiting groove and a rearward position where the limiting piece is positioned at a front end of the limiting groove. The shield cage assembly can also include an internal heat sink provided in a front segment of an internal receiving space of the partitioning bracket in some cases.

In other aspects, the side wall of the guiding shield cage also includes an elastic holding piece, and a side wall of the partitioning bracket also includes an avoiding opening which allows the elastic holding piece to pass through. In another implementation, a side wall of the guiding shield cage includes a holding member, the movable heat sink also includes a first holding portion on a side wall of the movable heat sink and a second holding portion on the side wall of the movable heat sink, the holding member of the side wall of the guide shielding cage latches with the first holding portion when the movable heat sink is in the front position, and the holding member of the side wall of the guide shielding cage latches with the second holding portion when the movable heat sink is in the rearward position.

In still other aspects, the movable heat sink includes a movable heat dissipating member and a movable pressure-applying spring, and the movable pressure-applying spring includes a spring piece which presses against a wall of the partitioning bracket. The movable heat sink also includes a guiding member in another implementation. The guiding shield cage also includes a guiding rail groove in some cases, and the guiding member is provided to the guiding rail groove such that the guiding member can slide forwardly or rearwardly. The partitioning bracket can include a receiving notch provided on a side wall of the partitioning bracket and, when the movable heat sink is positioned in the front position, the guiding member of the movable heat sink is received in the receiving notch of the partitioning bracket.

The movable heat sink can also include a lower stopping portion which enters into a lower receiving space of the guiding shield cage in some cases. When the movable heat sink is in the front position, a pluggable module inserted into the lower receiving space can push the movable heat sink to the rearward position. In other aspects, the shield cage assembly also includes side heat sinks. The side heat sinks can be positioned to outer sides of two side walls of the guiding shield cage respectively and move together with the movable heat sink.

Another example shield cage assembly includes a guiding shield cage and a movable heat sink. The guiding shield cage includes a holding member on a side wall. The movable heat sink includes a first holding portion on a side wall of the movable heat sink and a second holding portion on the side wall of the movable heat sink. The holding member of the side wall of the guide shielding cage latches with the first holding portion when the movable heat sink is in a front position, and the holding member of the side wall of the guide shielding cage latches with the second holding portion when the movable heat sink is in a rearward position.

An example connector assembly includes a guiding shield cage, a receptacle connector provided within the guiding shield cage, a partitioning bracket provided in the guiding shield cage, and a movable heat sink assembled to the partitioning bracket. The movable heat sink includes a lower stopping portion which enters into a lower receiving space of the guiding shield cage. When the movable heat sink is in a front position, a pluggable module inserted into the lower receiving space can push the movable heat sink to a rearward position.

### BRIEF DESCRIPTION OF THE DRAWINGS

Other features and effects of the present disclosure will be apparent from an embodiment illustrated in the drawings, in which:

FIG. 1 is a perspective view of a first embodiment of a connector assembly of the present disclosure and a pluggable module;

FIG. 2 is a perspective exploded view of the first embodiment;

FIG. 3 is a cross sectional view of the first embodiment with an upper heat sink and a lower heat dissipating member omitted and a movable heat sink positioned in a front position;

FIG. 4 is a cross sectional view of the first embodiment with the upper heat sink and the lower heat dissipating member omitted and the movable heat sink positioned in a rearward position;

FIG. 5 is a perspective exploded view of a guiding shield cage, a partitioning bracket, an internal heat sink and the movable heat sink of the first embodiment;

FIG. 6 is a perspective exploded view of the partitioning bracket, the internal heat sink and the movable heat sink of the first embodiment;

FIG. 7 is a perspective exploded view of the partitioning bracket, the internal heat sink and the movable heat sink of the first embodiment viewed from another angle;

FIG. 8 is a partial perspective view of the first embodiment with the movable heat sink being in the front position;

FIG. 9 is the first embodiment of a cross sectional view with movable heat sink being in the front position;

FIG. 10 is a partial perspective view of the first embodiment with movable heat sink being in the rearward position;

FIG. 11 is the first embodiment of a cross sectional view with the movable heat sink being in the rearward position;

FIG. 12 is a cross sectional view similar to FIG. 4 with the pluggable module pushing the movable heat sink to the rearward position;

FIG. 13 is a perspective exploded view of a guiding shield cage, a partitioning bracket, an internal heat sink and a movable heat sink of a second embodiment of the connector assembly of the present disclosure;

FIG. 14 is a partial perspective view of the second embodiment with the movable heat sink being in the front position;

FIG. 15 is a partial perspective view of the second embodiment with the movable heat sink being in the rearward position;

FIG. 16 is a perspective view of a third embodiment of the connector assembly of the present disclosure with an upper heat sink and a lower heat dissipating member omitted;

FIG. 17 is a perspective exploded view of FIG. 16 with a receptacle connector further omitted;

FIG. 18 is a perspective exploded view of a partitioning bracket and a movable heat sink of the third embodiment;

FIG. 19 is a cross sectional view of the third embodiment with the upper heat sink and the lower heat dissipating member omitted and the movable heat sink positioned in a front position;

FIG. 20 is a cross sectional view of the third embodiment with the upper heat sink and the lower heat dissipating member omitted and the movable heat sink positioned in a rearward position;

FIG. 21 is a partial perspective view of the third embodiment with the movable heat sink being in the front position;

FIG. 22 is a partial perspective view of the third embodiment with the movable heat sink being in the rearward position;

FIG. 23 is a partial broken side view of the third embodiment with the movable heat sink being in the front position;

FIG. 24 is a stepped cross sectional view partially broken and taken along a line A-A of FIG. 23 with the movable heat sink being in the front position;

FIG. 25 is a partially broken side view of the third embodiment with the movable heat sink being in the rearward position; and

FIG. 26 is a stepped cross sectional view partially broken and taken along a line B-B of FIG. 25 with the movable heat sink being in the rearward position.

### DETAILED DESCRIPTION OF THE PREFERRED EMBODIMENTS

Before the present disclosure is described in detail, it is noted that like elements are represented by the same reference numerals in the following description.

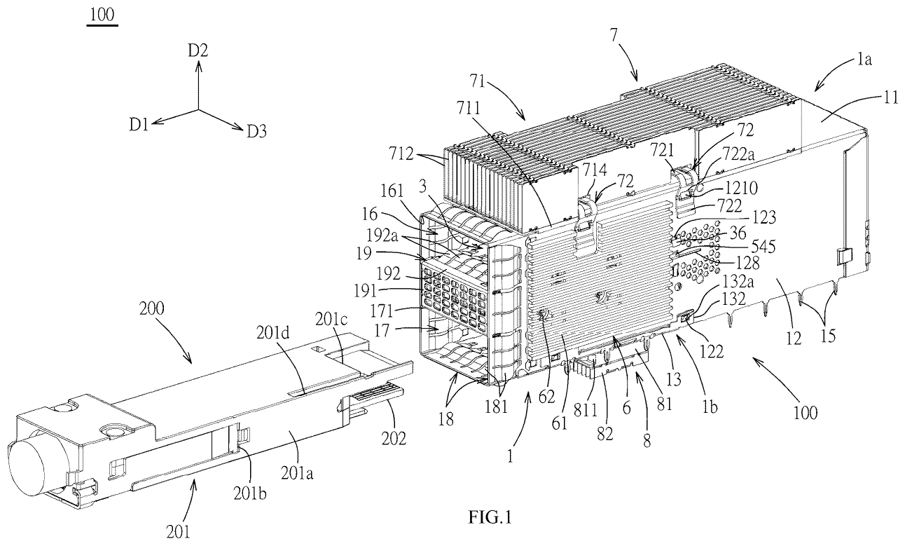

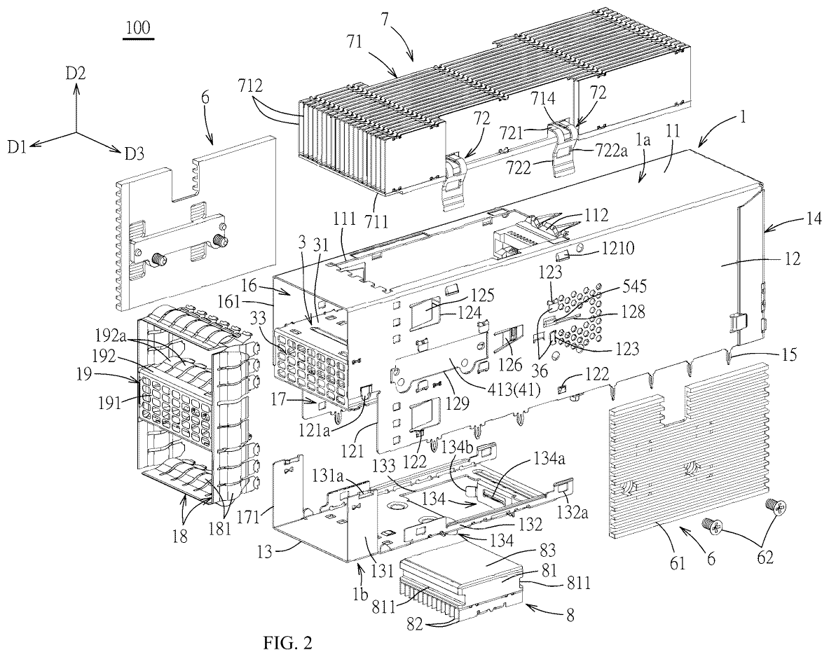

Referring to FIG. 1 and FIG. 2, a first embodiment of a connector assembly 100 of the present disclosure is adapted to be provided with a circuit board (not shown) and is adapted to mate with a pluggable module 200. The connector assembly 100 includes a guiding shield cage 1, a receptacle connector 2, a partitioning bracket 3, an internal heat sink 4, a movable heat sink 5, two side heat sinks 6, an upper heat sink 7 and a lower heat dissipating member 8.

The guiding shield cage 1 for example is formed by processing, such as stamping and bending, a metal plate. The guiding shield cage 1 extends along a front-rear direction D1 (a direction to which an arrow points is front, and an opposite direction is rear), and has a top wall 11 which is positioned to the up in an up-down direction D2 (a direction to which an arrow points is up, and an opposite direction is down), two side walls 12 which extend downwardly from two sides of the top wall 11 respectively and face each other in a left-right direction D3 (a direction to which an arrow points is right, and an opposite direction is right), a bottom wall 13 which is connected to front segments of bottom edges of the two side walls 12, a rear wall 14 which is connected to a rear edge of the top wall 11 and rear edges of the two side walls 12, and a plurality of pressing fit legs 15 which are formed to the bottom edges of the two side walls 12 and a bottom edge of the rear wall 14, the plurality of pressing fit legs 15 are used to press into a plurality of pressing fit holes of the circuit board respectively so that the guiding shield cage 1 is fixedly provided to the circuit board and may be electrically connected to a ground wiring of the circuit board.

In the first embodiment, the guiding shield cage 1 includes an upper shell 1a and a lower shell 1b which are assembled with each other, the upper shell 1a has the top wall 11 and the two side walls 12 which are integrally connected with each other, the lower shell 1b has the bottom wall 13, and the lower shell 1b is provided to the two side walls 12 of the upper shell 1a by assembling. A recessed portion 121 is formed to the bottom edge of each side wall 12 of the upper shell 1a close to a front end of each side wall 12, and each side wall 12 are outwardly formed with a plurality of latching blocks 122. The bottom wall 13 of the lower shell 1b is integrally upwardly formed with two protruding portions 131 which correspondingly cooperate with the two recessed portions 121 of the two side walls 12 respectively and two side assembling portions 132 which are correspondingly assembled to outer sides of the two side walls 12 respectively. The recessed portion 121 is provided with a front inserting portion 121a, the protruding portion 131 is provided with a front inserting hole 131a which correspondingly cooperates with the front inserting portion 121a, the front inserting portion 121a inserts into the front inserting hole 131a, each side assembling portion 132 is formed with a plurality of latching holes 132a which latch with the plurality of latching blocks 122 of the corresponding side wall 12, so that the bottom wall 13 of the lower shell 1b can be assembled and engaged with the two side walls 12 of the upper shell 1a.

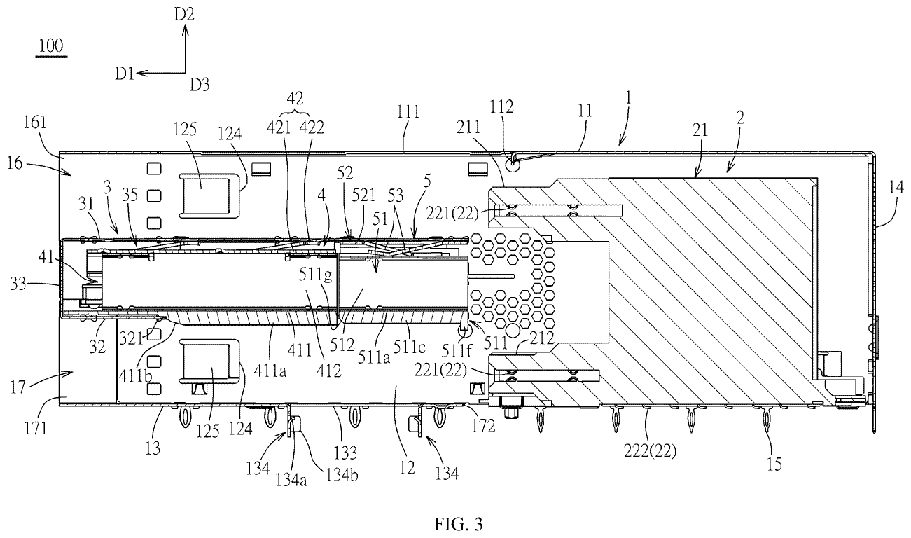

Referring to FIG. 3, the receptacle connector 2 is provided on the circuit board and is provided to a rear segment of an interior of the guiding shield cage 1, the receptacle connector 2 has a housing 21 which is insulative and a plurality of terminals 22 which are provided to the housing 21, the housing 21 has an upper receptacle 211 and a lower receptacle 212 which are toward the front and are arranged along the up-down direction D2, each terminal 22 has a contacting portion 221 which is positioned in the upper receptacle 211 or the lower receptacle 212 and a tail portion 222 which downwardly extends out of a bottom portion of the housing 21 and is used to be mechanically and electrically connected to the circuit board, the tail portion 222 of the embodiment constitutes a surface mounting form, however also may be constructed as a through-hole welding form.

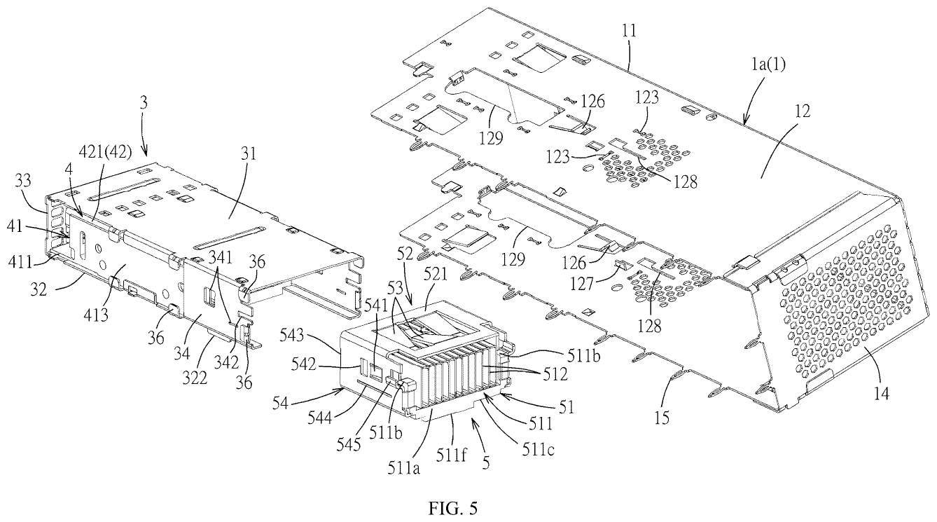

Referring to FIG. 1, FIG. 2 and FIG. 4 to FIG. 7, the partitioning bracket 3 is provided in the guiding shield cage 1, and the partitioning bracket 3 and the guiding shield cage 1 together define an upper receiving space 16 which corresponds to the upper receptacle 211 of the receptacle connector 2 and a lower receiving space 17 which corresponds to the lower receptacle 212 of the receptacle connector 2, a rear segment of the upper receiving space 16 and a rear segment of the lower receiving space 17 are communicated with each other so as to provide a space of a rear segment of the guiding shield cage 1 which is used to receive the receptacle connector 2. The upper receiving space 16 has an upper inserting port 161 which is positioned in the front of the upper receiving space 16 and allows the pluggable module 200 to insert therein, the lower receiving space 17 has a lower inserting port 171 which is positioned in the front of the lower receiving space 17 and allows the pluggable module 200 to insert therein and a bottom opening 172 which is positioned at the rear of a bottom portion of the lower receiving space 17 and is defined together by the two side walls 12, the bottom wall 13 and the rear wall 14 of the guiding shield cage 1, the bottom opening 172 allows the receptacle connector 2 to enter into from down to up so that the receptacle connector 2 is received in the rear segment of the interior of the guiding shield cage 1. In the first embodiment, the partitioning bracket 3 has an upper wall 31 and a lower wall 32 which face each other in the up-down direction, a front wall 33 which is connected to a front edge of the upper wall 31 and a front edge of the lower wall 32, and two side walls 34 which are connected to rear segments of side edges of the upper wall 31 and rear segments of side edges of the lower wall 32, the upper wall 31, the lower wall 32, the front wall 33 and the two side walls 34 together define an internal receiving space 35. Each side wall 12 of the guiding shield cage 1 has a fixing hole 123 which is penetratingly formed, the partitioning bracket 3 further has fixing bendable pieces 36 which extend to outer sides of the two side walls 12 respectively, the fixing bendable pieces 36 respectively pass through the fixing holes 123 of the two side walls 12 and then are bent and fixed, so that the partitioning bracket 3 is stably assembled to the guiding shield cage 1.

In the first embodiment, the connector assembly 100 may be provided to a mounting hole (not shown) of a casing (not shown), the guiding shield cage 1 is provided with a plurality of first grounding members 18 which is positioned at a front end of the guiding shield cage 1, the partitioning bracket 3 is further provided with a second grounding member 19 which is positioned at the front wall 33 and a front segment of the upper wall 31 and a front segment of the lower wall 32. The plurality of first grounding members 18 have a plurality of first elastic fingers 181 which extend rearwardly from the front end of the guiding shield cage 1 and are distributed to an outer side of the guiding shield cage 1 and an inner side of the guiding shield cage 1, the first elastic finger 181 of the plurality of first elastic fingers 181 which is positioned at the outer side of the guiding shield cage 1 is used to contact an edge of the mounting hole of the casing, the first elastic finger 181 of the plurality of first elastic fingers 181 which is positioned at the inner side of the guiding shield cage 1 is used to contact the pluggable module 200. The second grounding member 19 has a piece body 191 which is provided to a front side surface of the front wall 33 of the partitioning bracket 3 and two grounding pieces 192 which rearwardly extend respectively from an upper edge of the piece body 191 and a lower edge of the piece body 191 so as to respectively enter into the upper receiving space 16 and the lower receiving space 17. Each grounding piece 192 has a plurality of second elastic fingers 192a which extend rearwardly and are used to contact the pluggable module 200, the second elastic finger 192a of the plurality of second elastic fingers 192a which enters into the upper receiving space 16 is provided to the front segment of the upper wall 31, the second elastic finger 192a of the plurality of second elastic fingers 192a which enters into the lower receiving space 17 is provided to the front segment of the lower wall 32.

The pluggable module 200 has a shell member 201 and a mating circuit board 202. The shell member 201 has an inserting portion 201a which is used to insert into the upper receiving space 16 or the lower receiving space 17, the mating circuit board 202 protrudes from the inserting portion 201a, is provided to the inserting portion 201a and is used to insert into the upper receptacle 211 or the lower receptacle 212. Each side wall 12 of the guiding shield cage 1 has two openings 124 which respectively correspond to the upper receiving space 16 and the lower receiving space 17, an inward extending elastic piece 125 is constructed at each opening 124 and extends rearwardly and obliquely toward the interior of the guiding shield cage 1. A left side and a right side of the inserting portion 201a of the pluggable module 200 each are provided with a locking recessed groove 201b which correspondingly cooperates with the inward extending elastic piece 125, the inward extending elastic pieces 125 at the openings 124 are used to cooperate with the locking recessed grooves 201b of the pluggable module 200 which inserts into the upper receiving space 16 or the lower receiving space 17, so as to generate locking effect. In addition, an aligning structure 201c is further formed at a top portion of a front end of the inserting portion 201a of the shell member 201. The top wall 11 of the guiding shield cage 1 is formed with an upper window 111 which is communicated with the upper receiving space 16 and an upper stopping portion 112 which extends downwardly into the upper receiving space 16 from a rear segment of the upper window 111, the upper stopping portion 112 is used to stop the aligning structure 201c so as to limit an inserting position of the pluggable module 200. The lower wall 32 of the partitioning bracket 3 is formed with a lower window 321 which makes the internal receiving space 35 communicated with the lower receiving space 17.

Referring to FIG. 1 and FIG. 4 to FIG. 7, the internal heat sink 4 is provided to a front segment of the internal receiving space 35 of the partitioning bracket 3 and has an internal heat dissipating member 41 and an internal pressure-applying spring 42 which is provided between the internal heat dissipating member 41 and the upper wall 31 of the partitioning bracket 3. The internal heat dissipating member 41 has a base plate 411 and a plurality of heat dissipating fins 412 which are arranged side by side along left-right direction D3, latch with each other and are provided to a top surface of the base plate 411, the base plate 411 has a thermal coupling portion 411a which passes through the lower window 321 to enter into the lower receiving space 17, a front end of the thermal coupling portion 411a has a guiding edge 411b. The internal pressure-applying spring 42 has a pressing plate 421 which presses against a top portion of the internal heat dissipating member 41 and a plurality of plate-shaped spring pieces 422 which extend from the pressing plate 421 and press against the upper wall 31 of the partitioning bracket 3, it is noted that, the internal pressure-applying spring 42 also may be a spring structure in other form and is not limited to the first embodiment. When the pluggable module 200 inserts into the lower receiving space 17, the pluggable module 200 can raise the internal heat dissipating member 41 by means of the guiding edge 411b so that the pluggable module 200 contacts the thermal coupling portion 411a, at the same time the raised internal heat dissipating member 41 compresses the pressure-applying spring 42 so that the pressure-applying spring 42 provides an elastic acting force. By the elastic force applied by the internal pressure-applying spring 42 on the internal heat dissipating member 41, the internal heat dissipating member 41 can be moved relative to the partitioning bracket 3 along the up-down direction D2, and the thermal coupling portion 411a of the internal heat dissipating member 41 is applied with the elastic force and contacts the pluggable module 200, so as to assure contact completeness and strengthen heat dissipating performance.

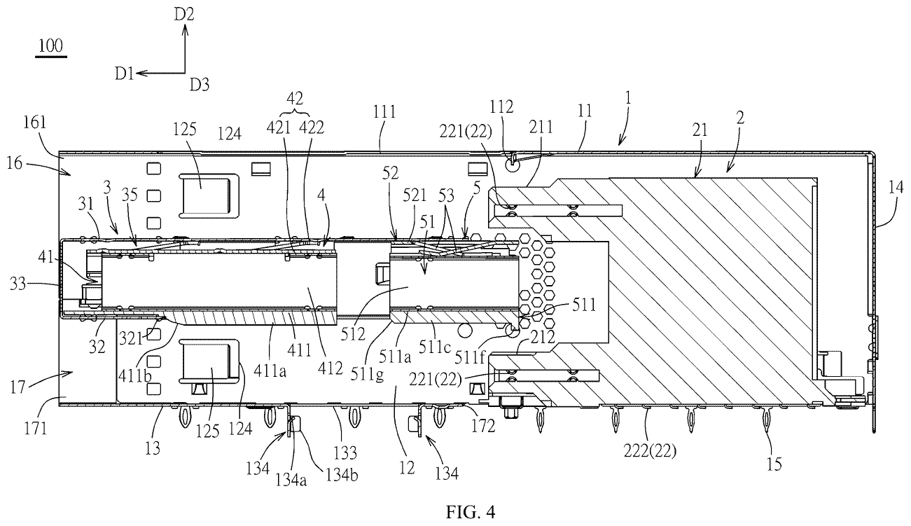

Referring to FIG. 1 and FIG. 3 to FIG. 6, a rear end of the partitioning bracket 3 is positioned in front of a front end of the upper receptacle 211 and a front end of the lower receptacle 212, the movable heat sink 5 is assembled to the rear end of the partitioning bracket 3 and is positioned behind the internal heat sink 4. Detailedly, in the first embodiment, the partitioning bracket 3 limits the movable heat sink 5 to move in the up-down direction D2 and the left-right direction D3, so that the movable heat sink 5 can move relative to the partitioning bracket 3 between a front position where the movable heat sink 5 is positioned in front of the front end of the upper receptacle 211 and the front end of the lower receptacle 212 (see FIG. 3) and a rearward position where the movable heat sink 5 at least partially enters into between the upper receptacle 211 and the lower receptacle 212 (see FIG. 4). Specifically, the partitioning bracket 3 limits the movable heat sink 5 to move in the up-down direction D2 by the upper wall 31 and the lower wall 32 which is formed with the lower window 321, and limits the movable heat sink 5 to move in the left-right direction D3 by the two side walls 34, so that the movable heat sink 5 only can move between the front position and the rearward position along the front-rear direction D1. In an assembling manner of the first embodiment, firstly the receptacle connector 2 is mounted to the circuit board, then the guiding shield cage 1 which is provided with the partitioning bracket 3 and the movable heat sink 5 cages the receptacle connector 2 from up to down and is fixed to the circuit board, so when the movable heat sink 5 is positioned in the front position where the movable heat sink 5 is in front of the front end of the upper receptacle 211 and the front end of the lower receptacle 212, the movable heat sink 5 can avoid the upper receptacle 211 of the receptacle connector 2 to avoid the movable heat sink 5 and the upper receptacle 211 of the receptacle connector 2 generating interference problem to affect assembling. And, after the assembling is completed, the movable heat sink 5 may be again moved rearwardly to the rearward position where the movable heat sink 5 enters into between the upper receptacle 211 and the lower receptacle 212, so that the partitioning bracket 3 together with the movable heat sink 5 play complete partitioning function. Generally, by the movable heat sink 5 which can move between the front position and the rearward position, in a precondition that the partitioning bracket 3 together with the movable heat sink 5 subsequently can play complete partitioning function, the interference problem generated between the movable heat sink 5 and the receptacle connector 2 in assembling process can be avoided, which is beneficial to assembling operation. Importantly, by means of the internal heat sink 4 and the movable heat sink 5 which is positioned in the rearward position, a distance between the internal heat sink 4 and the movable heat sink 5 can be lengthened, and a range where heat dissipating is performed on the pluggable module 200 can be enlarged, in turn heat dissipating efficacy is promoted.

The movable heat sink 5 includes a movable heat dissipating member 51 and a movable pressure-applying spring. The movable pressure-applying spring includes a movable supporting frame 52 and a plurality of movable pressure-applying elastic pieces 53. The movable heat dissipating member 51 is assembled in the movable supporting frame 52, the movable heat dissipating member 51 includes a base 511 and a plurality of heat dissipating fins 512. The base 511 has a lower wall 511a and two side assembling plates 511b which are integrally constructed to extend upwardly from a left side and a right side edge of the lower wall 511a respectively, the lower wall 511a of the base 511 has a thermal coupling portion 511c which downwardly enters into the lower receiving space 17 via the lower window 321, a front end of the thermal coupling portion 511c has a guiding edge 511g, the plurality of heat dissipating fins 512 are arranged side by side along the left-right direction D3, latch with each other and are provided to a top surface of the base 511. The movable supporting frame 52 has an upper wall 521 and two side walls 54 which extend downwardly from the upper wall 521, each side assembling plate 511b at each of two sides of the movable heat dissipating member 51 has a latching aperture 511d, each side wall 54 has a latching piece 541 which obliquely extends inwardly and rearwardly and is used to latch with the latching aperture 511d, a width of the latching aperture 511d in the up-down direction D2 is larger than a width of the latching piece 541, by that the two side assembling plates 511b at the two sides of the movable heat dissipating member 51 are assembled to the two side walls 54 of the movable supporting frame 52 in a manner that the two side assembling plates 511b can float in the up-down direction, the movable heat dissipating member 51 can move in the up-down direction D2 relative to the movable supporting frame 52, on the other hand, the movable supporting frame 52 can limit the movable heat dissipating member 51 to move in the left-right direction D3 by the two side walls 54, the movable supporting frame 52 can limit a distance of the movable heat dissipating member 51 moving in the up-down direction D2 by the upper wall 521 and lower edges of the two side walls 54 which are inwardly bent. The plurality of movable pressure-applying elastic pieces 53 are integrally constructed to be provided to the upper wall 521 of the movable supporting frame 52, and obliquely extend downwardly to apply elastic forces to the plurality of heat dissipating fins 512 of the movable heat dissipating member 51, so that the movable heat dissipating member 51 can elastically move in the up-down direction relative to the movable supporting frame 52 and the partitioning bracket 3. When the pluggable module 200 inserts into the lower receiving space 17, the pluggable module 200 can raise the movable heat dissipating member 51 by means of the guiding edge 511g, so that the pluggable module 200 contacts the thermal coupling portion 511c, at the same time the raised movable heat dissipating member 51 compresses the plurality of movable pressure-applying elastic pieces 53 so that the plurality of movable pressure-applying elastic pieces 53 provide elastic acting forces. With the elastic forces applied to the movable heat dissipating member 51 by the plurality of movable pressure-applying elastic pieces 53, the movable heat dissipating member 51 can be moved along the up-down direction D2 relative to the movable supporting frame 52, and the thermal coupling portion 511c of the movable heat dissipating member 51 is applied with the elastic forces and contacts the pluggable module 200, so as to assure contact completeness and strengthen heat dissipating performance. The two side walls 54 of the movable supporting frame 52 are constructed as the two side walls 54 of the movable heat sink 5.

The two side walls 12 of the guiding shield cage 1 have holding members 126, the two side walls 54 of the movable heat sink 5 have first holding portions 542 which latch with the holding members 126 respectively when the movable heat sink 5 is in the front position and second holding portions 543 which latch with the holding members 126 respectively when the movable heat sink 5 is in the rearward position. Specifically, the holding members 126 in the first embodiment are two elastic holding pieces which are respectively constructed on the two side walls 12 of the guiding shield cage 1 and extend inwardly. The first holding portions 542 of the movable heat sink 5 are limiting holes which are constructed on the two side walls 54 of the movable heat sink 5 respectively, the second holding portions 543 of the movable heat sink 5 are front edges which are constructed on the two side walls 54 of the movable heat sink 5 respectively.

In addition, each side wall 54 and each side assembling plate 511b of the movable heat sink 5 further respectively have limiting grooves 544, 511e, each side wall 12 of the guiding shield cage 1 further has a limiting piece 127 which is positioned behind the corresponding holding member 126 and inwardly extends to correspondingly enter into the limiting grooves 544, 511e, each side wall 34 of the partitioning bracket 3 has two avoiding openings 341 which respectively allow the holding member 126 (the elastic holding piece) and the limiting piece 127 to pass through. In a varied embodiment, the holding member 126 (the elastic holding piece) and the limiting piece 127 may be constructed on each side wall 34 of the partitioning bracket 3. A rear end of each side wall 54 of the movable heat sink 5 has a guiding member 545 which extends outwardly and bends upwardly and is sheet-shaped, each side wall 34 of the partitioning bracket 3 has a guiding member receiving notch 342 which is positioned to the rear end of each side wall 34 of the partitioning bracket 3 and is used to receive a part of the guiding member 545 which extends outwardly, each side wall 12 of the guiding shield cage 1 has a guiding rail groove 128, the part of the guiding member 545 which extends outwardly is provided to the guiding rail groove 128 so as to be capable of sliding forwardly or rearwardly, in addition, a front segment of the guiding rail groove 128 has a hole which is larger, so the part of the guiding member 545 which bends upwardly can correspondingly passes through the hole in an assembling process of the movable heat sink 5, the partitioning bracket 3 and the guiding shield cage 1. It is noted that, in other embodiments, the guiding members 545 also may be provided to the two side walls 12 of the guiding shield cage 1 respectively, the guiding rail grooves 128 also may be provided to the two side walls 54 of the movable heat sink 5 respectively.

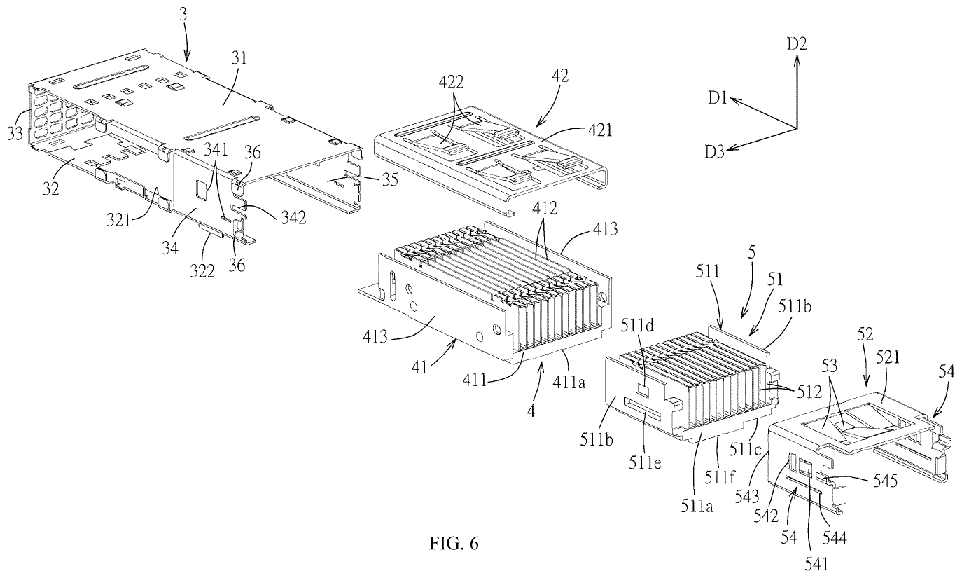

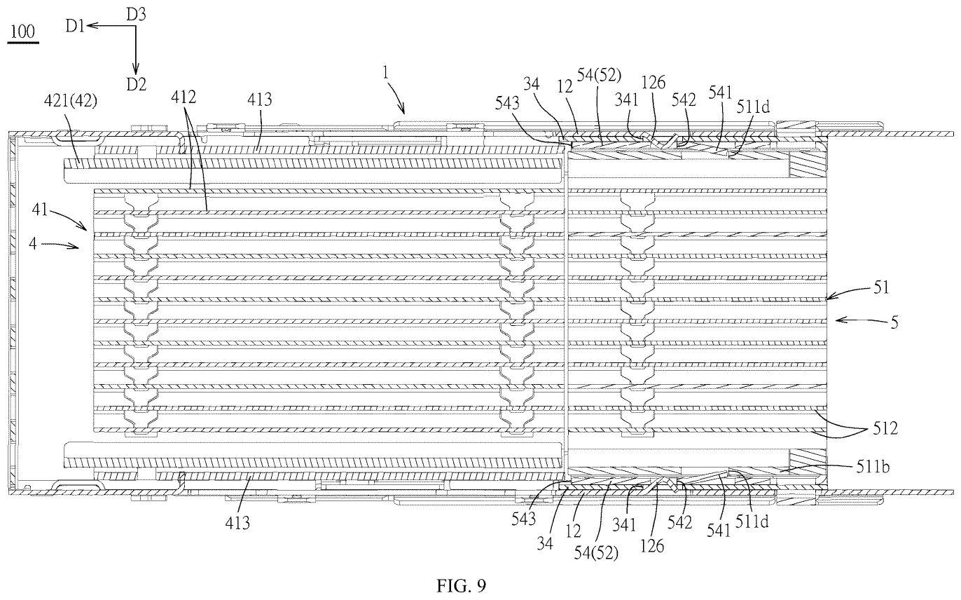

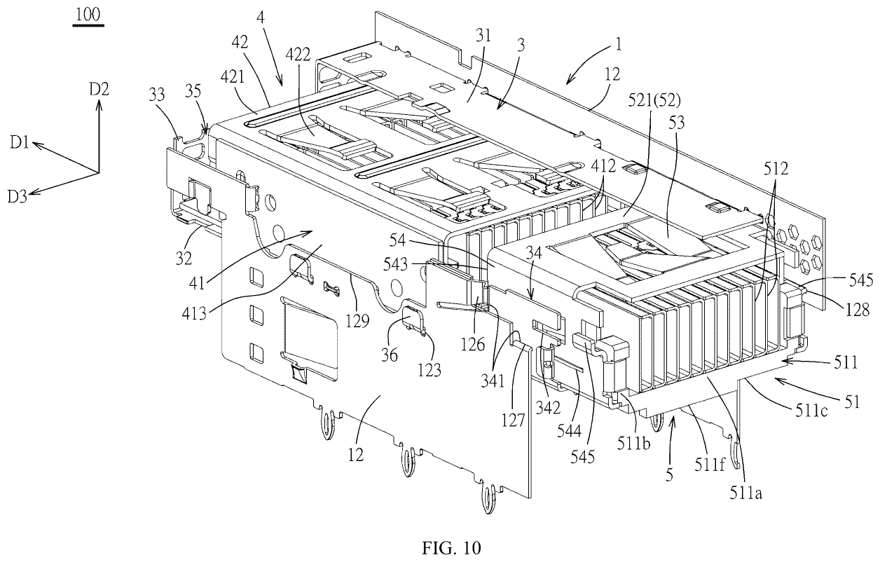

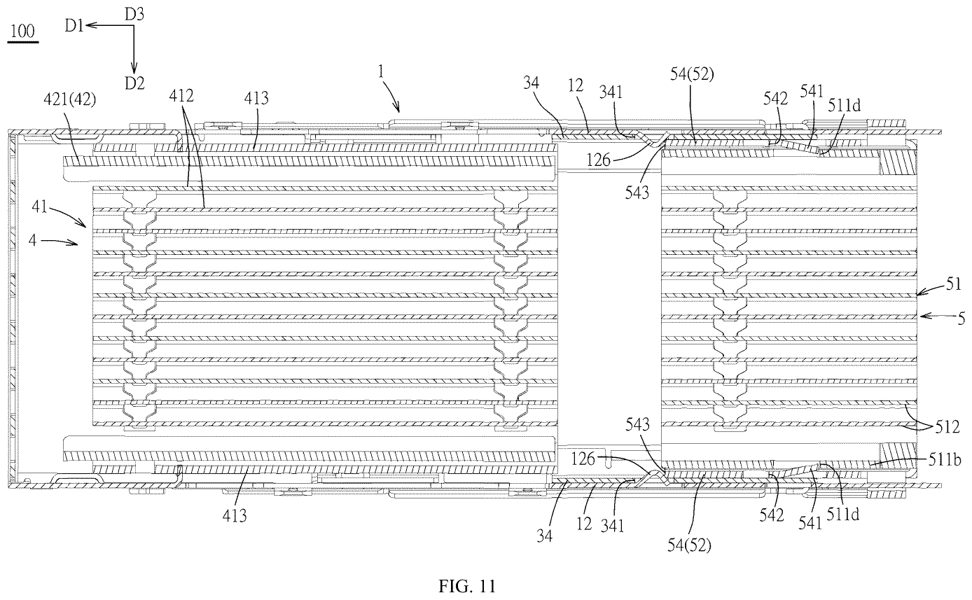

Specifically, referring to FIG. 3, FIG. 6 and FIG. 8 to FIG. 9, when the movable heat sink 5 is in the front position, the movable heat sink 5 is substantially received in a rear segment of the internal receiving space 35 of the partitioning bracket 3, the elastic holding piece (the holding member 126) latches with the limiting hole (the first holding portion 542), the limiting piece 127 is positioned to a rear end of the limiting groove 544 and a rear end of the limiting groove 511e, the guiding member 545 is received in the guiding member receiving notch 342 and is positioned to a front end of the guiding rail groove 128; referring to FIG. 4, FIG. 6 and FIG. 10 to FIG. 11, when the movable heat sink 5 is moved to the rearward position from the front position, a front segment part of the movable heat sink 5 is received in the rear segment of the internal receiving space 35 of the partitioning bracket 3, a rear segment part of the movable heat sink 5 is rearwardly exposed from the internal receiving space 35 of the partitioning bracket 3, and enters into between the upper receptacle 211 and the lower receptacle 212, the elastic holding piece (the holding members 126) latches with the front edge (the second holding portion 543) of the two side walls 54 of the movable heat sink 5, the limiting piece 127 is positioned to a front end of the limiting groove 544 and a front end of the limiting groove 511e, the guiding member 545 leaves the guiding member receiving notch 342 and moves to a rear end of the guiding rail groove 128. By the corresponding latching cooperation between the holding member 126 and the first holding portion 542 and the corresponding latching cooperation between the holding member 126 and the second holding portion 543, the movable heat sink 5 can be positioned in the front position and the rearward position respectively, and by the corresponding cooperation between the limiting piece 127 and the limiting grooves 544,511e and the corresponding cooperation between the guiding member 545 and the guiding rail groove 128, the movable heat sink 5 can be subjected to sufficient guiding, limiting and supporting.

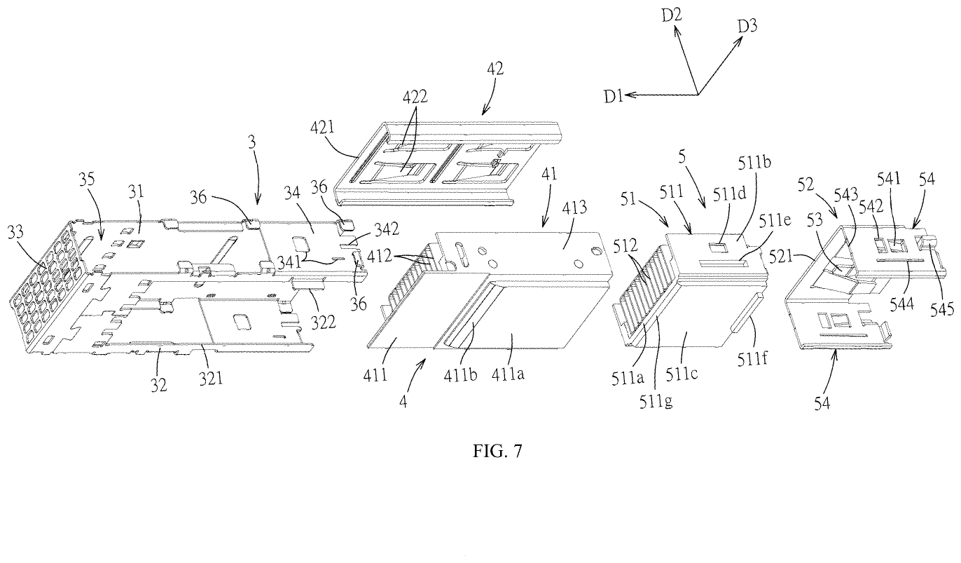

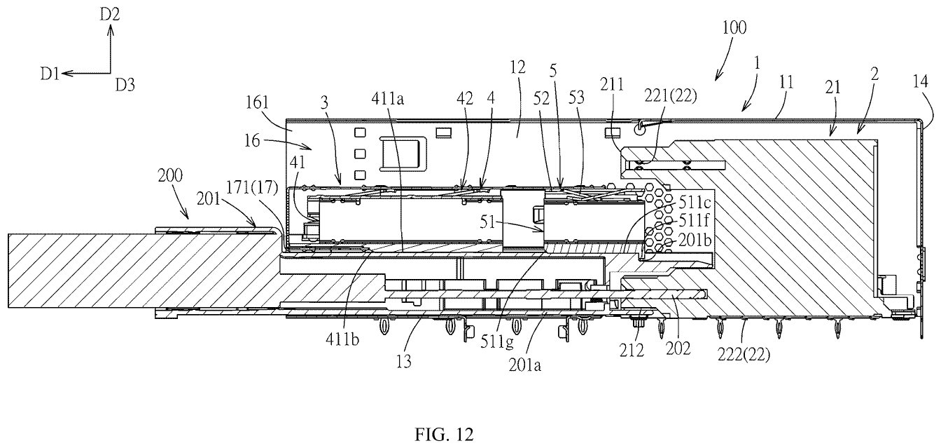

Referring to FIG. 6, FIG. 7 and FIG. 12, in addition, in the first embodiment, the lower wall 32 of the partitioning bracket 3 is further formed with an aligning portion 322 which bends downwardly from a side edge of the lower window 321, protrudes to enter into the lower receiving space 17 and is used to align with and guide an aligning groove 201d (see FIG. 1) of the pluggable module 200, a rear end edge of the thermal coupling portion 511c of the movable heat sink 5 of the movable heat dissipating member 51 has a lower stopping portion 511f which downwardly enters into the lower receiving space 17 and is used to stop the aligning structure 201c of the pluggable module 200 so as to limit the inserting position of the pluggable module 200, when the movable heat sink 5 is in the front position, the pluggable module 200 which enters into the lower receiving space 17 can push the lower stopping portion 511f to make the movable heat sink 5 rearwardly move to the rearward position, by this, the pluggable module 200 which enters into the lower receiving space 17 at a first time can employ the lower stopping portion 511f to push the movable heat sink 5 rearwardly to the rearward position while the pluggable module 200 enters into the lower receiving space 17 at the first time, which omits a manual operation step in assembling.

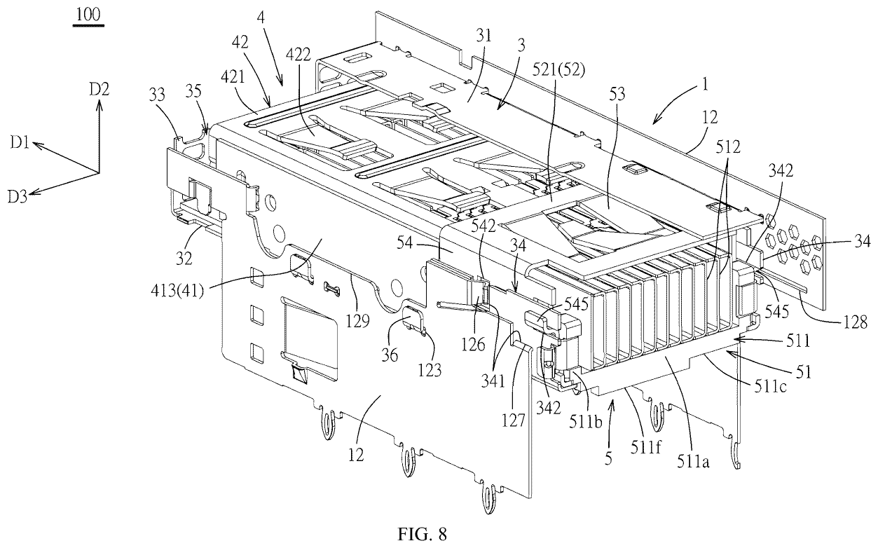

Referring to FIG. 1, FIG. 2, FIG. 6 and FIG. 8, a left side edge and a right side edge of the base plate 411 of the internal heat dissipating member 41 which is positioned in the internal receiving space 35 of the partitioning bracket 3 are integrally constructed and formed with two side plates 413 which extend upwardly, each side wall 12 of the guiding shield cage 1 has a side wall opening 129 which is communicated with the internal receiving space 35 of the partitioning bracket 3, the two side heat sinks 6 are provided to the two side plates 413 respectively from outer sides of the two side walls 12 of the guiding shield cage 1 by means of the two side wall openings 129, each side heat sink 6 includes a side heat dissipating member 61 and two screwing member 62 which fix the side heat dissipating member 61 to two screwing holes of the corresponding side plate 413, the two side heat sinks 6 can synergize with the internal heat dissipating member 41 of the internal heat sink 4 for heat dissipating, so as to enhance heat dissipating efficiency.

Referring to FIG. 1 to FIG. 3, the upper heat sink 7 includes an upper heat dissipating member 71 and two elastic clips 72. The upper heat dissipating member 71 is provided at the upper window 111 of the top wall 11 of the guiding shield cage 1, the upper heat dissipating member 71 has a base plate 711 which is provided to the top wall 11, a plurality of heat dissipating fins 712 which are arranged side by side along the left-right direction D3, latch with each other and are provided to a top surface of the base plate 711, and a thermal coupling portion (not shown) which is provided to a bottom surface of the base plate 711 and enters into the upper receiving space 16 via the upper window 111. The upper heat dissipating member 71 is assembled to the top wall 11 of the guiding shield cage 1 by the two elastic clips 72 in a manner that the upper heat dissipating member 71 can elastically move relative to the upper receiving space 16 and the thermal coupling portion of the upper heat dissipating member 71 elastically contacts the pluggable module 200 which inserts into the upper receiving space 16. Each elastic clip 72 has an elastic pressing portion 721 which extends along the left-right direction D3 and presses against the base plate 711 of the upper heat dissipating member 71 from above and two assembling portions 722 which respectively extend downwardly from two ends of the elastic pressing portion 721 and respectively latch with the two side walls 12 of the guiding shield cage 1, specifically, each side wall 12 which is positioned at each of the two sides of the top wall 11 is formed with two latching protrusions 1210, each assembling portion 722 is formed with a latching hole 722a which correspondingly latches with the latching protrusion 1210 of the corresponding side wall 12. In addition, the upper heat dissipating member 71 further has two avoiding recessed grooves 714 which are formed to the plurality of heat dissipating fins 712 and are used to avoid the two elastic pressing portions 721 respectively.

The bottom wall 13 of the guiding shield cage 1 is formed with a lower opening 133 which is communicated with the lower receiving space 17 and two latching plates 134 which are provided at a front end and a rear end of the lower opening 133 respectively and extend downwardly, the two latching plates 134 may be integrally constructed by the bottom wall 13, each latching plate 134 has a latching protuberance 134a which is integrally constructed and inwardly formed and two latching lugs 134b which are integrally constructed to be respectively formed at two side edges of the latching protuberance 134a. The lower heat dissipating member 8 has a base plate 81, a plurality of heat dissipating fins 82 which are arranged side by side along the left-right direction D3, latch with each other and are provided to the base plate 81, and a thermal coupling portion 83 which is provided to a top surface of the base plate 81 and is used to pass through the lower opening 133 to enter into the lower receiving space 17, the thermal coupling portion 83 of the lower heat dissipating member 8 is used to contact the pluggable module 200 which inserts into the lower receiving space 17. A front side edge and a rear side edge of the base plate 81 of the lower heat dissipating member 8 are formed with two latching recessed grooves 811 which are respectively assembled to the two latching plates 134 and extend along the left-right direction D3. The two latching protuberances 134a of the two latching plates 134 respectively latch with the two latching recessed grooves 811, the two latching lugs 134b may be bent to enter into the corresponding latching recessed groove 811, so the heat dissipating member 8 is stably assembled to the two latching plates 134 of the bottom wall 13.

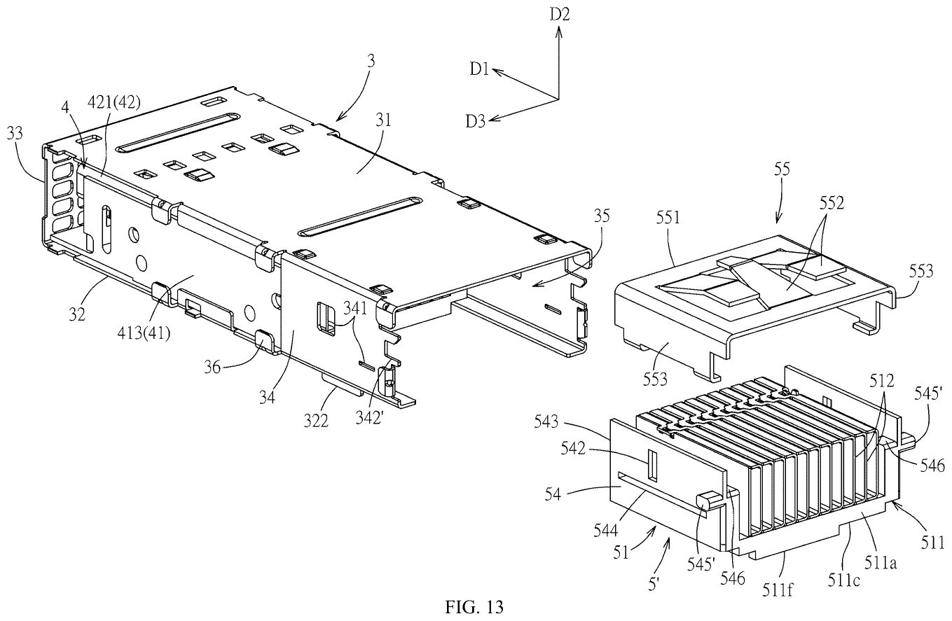

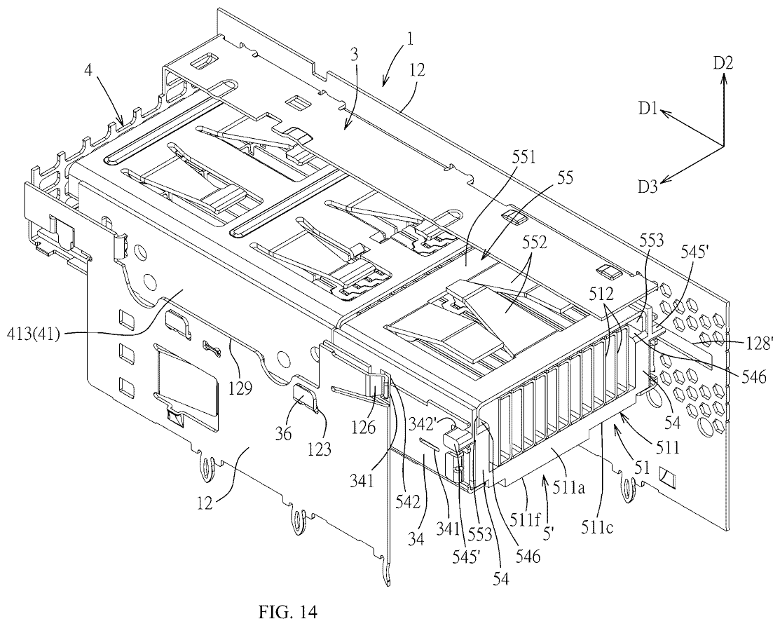

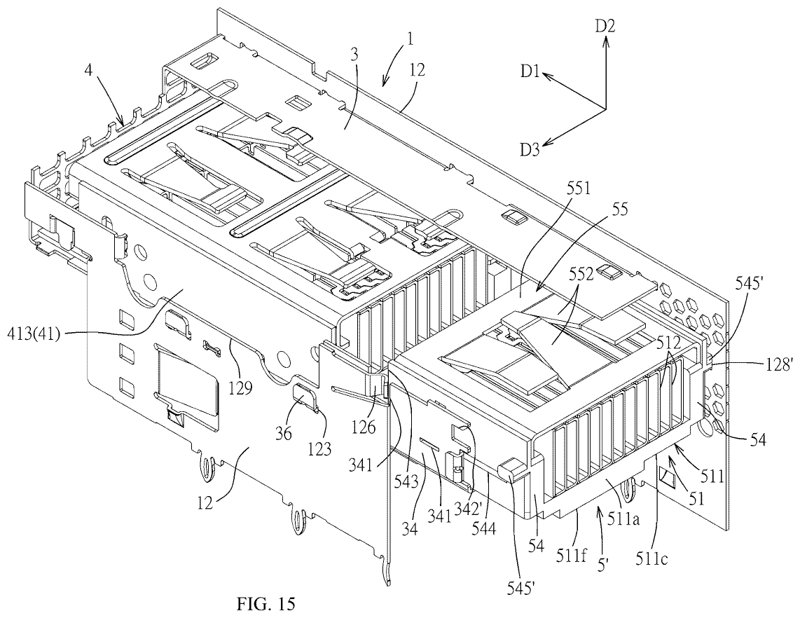

Referring to FIG. 13 to FIG. 15, a second embodiment of the connector assembly 100 of the present disclosure differs from the first embodiment in that, the movable heat sink 5′includes a movable heat dissipating member 51 and a movable pressure-applying spring 55. The movable heat dissipating member 51 has a base 511 and a plurality of heat dissipating fins 512. The base 511 has a lower wall 511a and two side walls 54 which are integrally constructed from a left side edge and a right side edge of the lower wall 511a respectively and extends upwardly, the lower wall 511a of the base 511 has a thermal coupling portion 511c which downwardly enters into the lower receiving space 17. The plurality of heat dissipating fins 512 are arranged side by side along the left-right direction D3, latch with each other and are provided to a top surface of the lower wall 511a. The movable pressure-applying spring 55 has a pressing plate 551 which presses against the movable heat dissipating member 51 and two side plates 553 which extend downwardly from a left side edge and a right side edge of the pressing plate 551 respectively, lower edges of the two side plates 553 of the movable pressure-applying spring 55 of the second embodiment are respectively positioned at inner sides of the two side walls 54 and respectively press against step portions 546 which are respectively positioned at the inner sides of the two side walls 54, the pressing plate 551 has a plurality of plate-shaped spring pieces 552 which press against the upper wall 31 of the partitioning bracket 3, it is noted that, the movable pressure-applying spring 55 also may be a spring structure in other form and is not limited to the second embodiment. The movable pressure-applying spring 55 is positioned between the movable heat dissipating member 51 and the upper wall 31 of the partitioning bracket 3, and applies an elastic force to the movable heat dissipating member 51, so that the movable heat dissipating member 51 can be elastically upwardly or downwardly moved relative to the partitioning bracket 3 along the up-down direction D2, and the thermal coupling portion 551c of the movable heat dissipating member 51 is applied with the elastic force and contacts the pluggable module 200 which inserts into the lower receiving space 17, so as to assure contact completeness and strengthen heat dissipating performance.

The two side walls 54 of the base 511 are constructed as the two side walls 54 of the movable heat sink 5′, and each side wall 54 is formed with the first holding portion 542 (the limiting hole), the second holding portion 543 (the front edge of the side wall 54 of the movable heat sink 5′), the limiting groove 544 and the guiding member 545′. In addition, the guiding member 545′ in the second embodiment is not sheet-shaped but is block-shaped and extends outwardly along the left-right direction D3, so a width of the guiding rail groove 128′, which correspondingly cooperates with the guiding member 545′, of the side wall 12 of the guiding shield cage 1 in the up-down direction D2 and a width of the guiding member receiving notch 342′, which correspondingly cooperates with the guiding member 545′, of the partitioning bracket 3 in the up-down direction D2 are also correspondingly larger than the first embodiment.

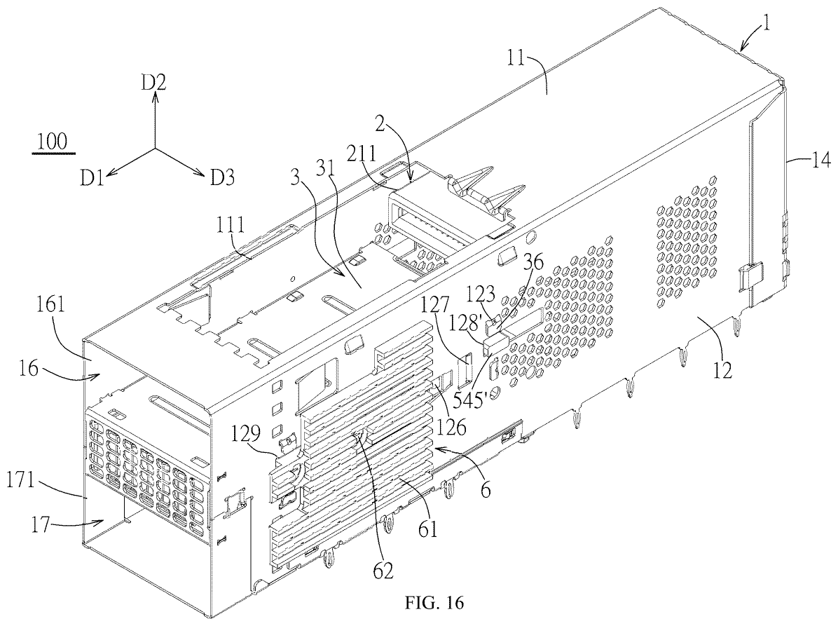

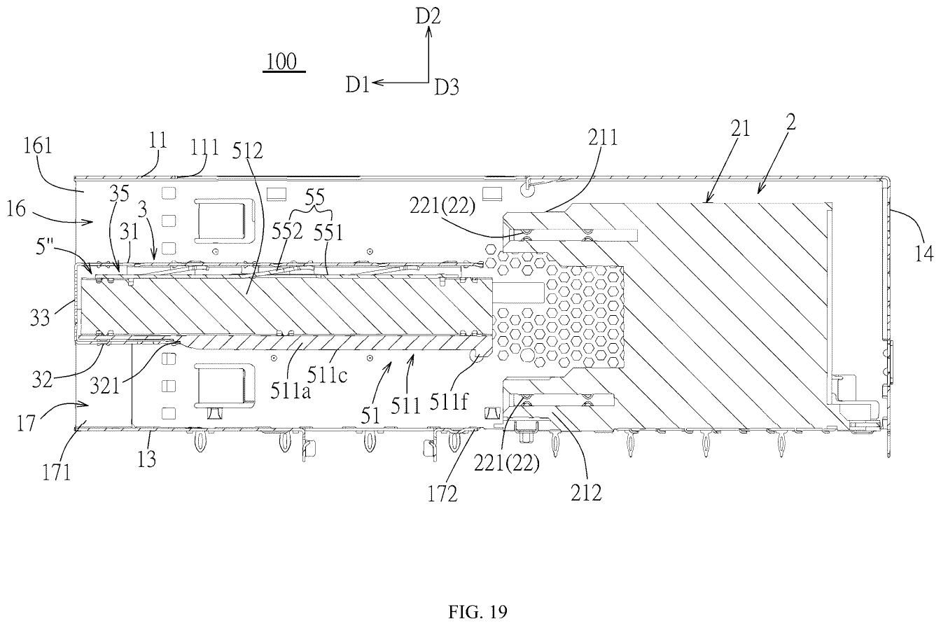

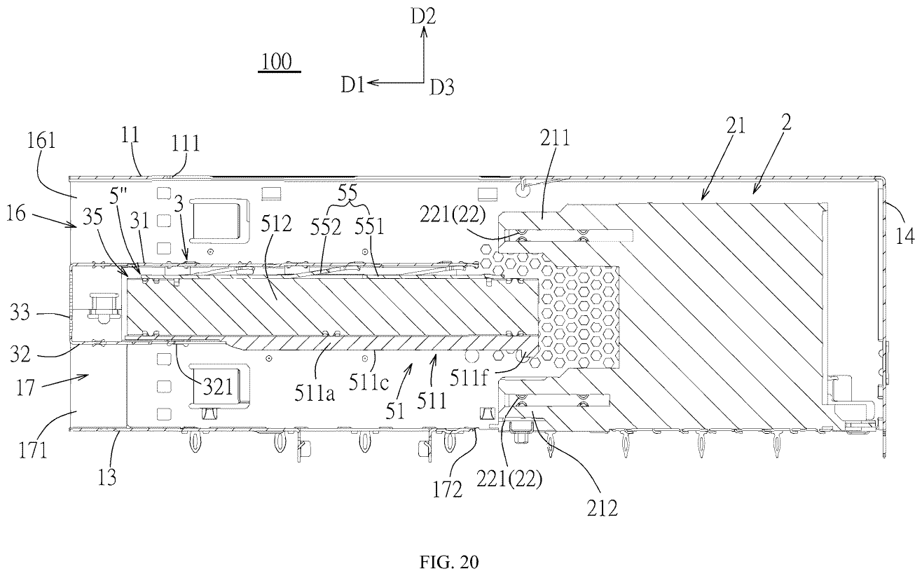

Referring to FIG. 16 to FIG. 20, a third embodiment of the connector assembly 100 of the present disclosure differs from the second embodiment in that, in the third embodiment, the internal heat sink 4 is omitted, the movable heat dissipating member 51 of the movable heat sink 5″ is provided in the internal receiving space 35 of the partitioning bracket 3, a length of the movable heat dissipating member 51 of the movable heat sink 5″ of the third embodiment in the front-rear direction D1 is longer, and similarly can move between the front position where the movable heat sink 5″ is positioned in front of the front end of the upper receptacle 211 and the front end of the lower receptacle 212 and the rearward position where the movable heat sink 5″ at least partially enters into between the upper receptacle 211 and the lower receptacle 212.

In the third embodiment, lower edges of the two side pressing portions 554 of the movable pressure-applying spring 55 press against inner sides of the two side walls 54 of the movable heat dissipating member 51 of the movable heat sink 5″, and each side pressing portion 554 has a positioning groove 554a which is recessed upwardly, each side wall 54 of the movable heat dissipating member 51 of the movable heat sink 5″ has a positioning block 547 which is positioned to the inner side of each side wall 54 and upwardly snaps into the positioning groove 554a. By that the positioning groove 554a and the positioning block 547 cooperate with each other, the movable pressure-applying spring 55 is assembled to the movable heat dissipating member 51 of the movable heat sink 5″ and moves together with the movable heat dissipating member 51.

The pressing plate 551 of the movable pressure-applying spring 55 similarly has a plurality of plate-shaped spring pieces 552 which press against the upper wall 31 of the partitioning bracket 3. The movable pressure-applying spring 55 is positioned between the movable heat dissipating member 51 and the upper wall 31 of the partitioning bracket 3, and applies an elastic force to the movable heat dissipating member 51, so that the movable heat dissipating member 51 of the movable heat sink 5″ can be elastically moved upwardly or downwardly along the up-down direction D2 relative to the partitioning bracket 3, and the thermal coupling portion 551c of the movable heat dissipating member 51 is applied with the elastic force and contacts the pluggable module 200 (see FIG. 1) which inserts into the lower receiving space 17, so as to assure contact completeness and strengthen heat dissipating performance.

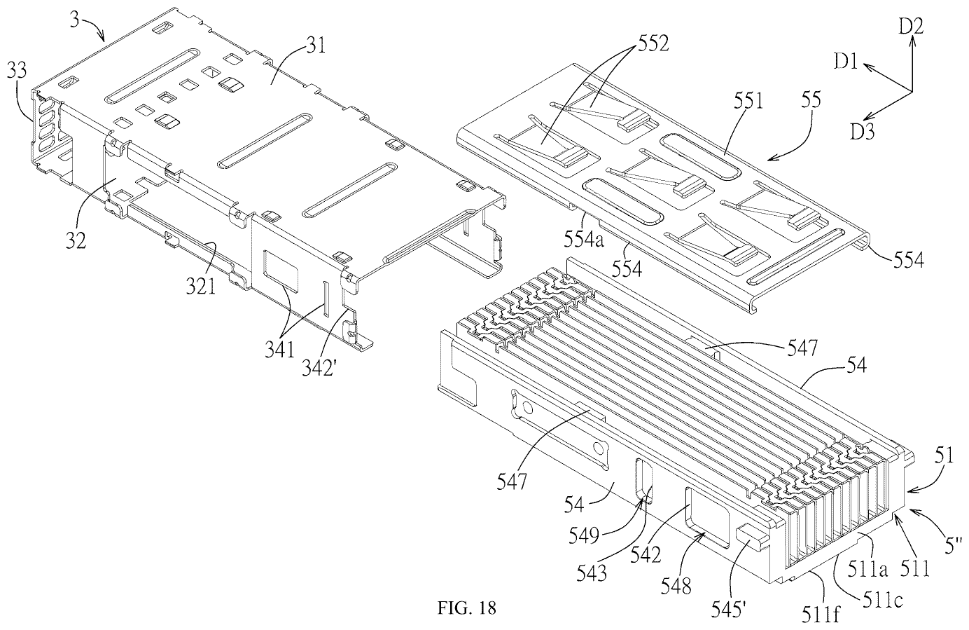

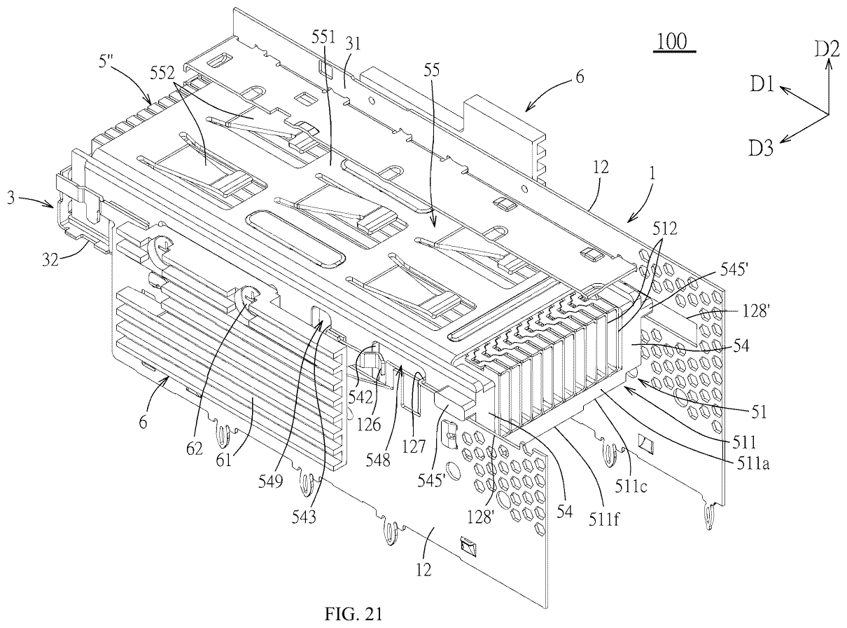

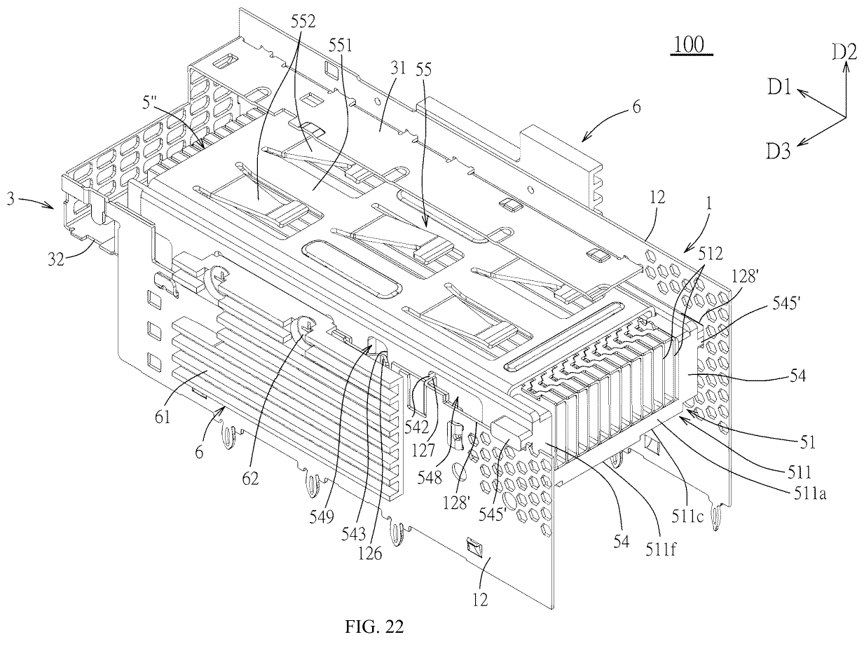

Referring to FIG. 18, FIG. 21 and FIG. 22, in addition, in the third embodiment, the two side walls 54 of the base 511 are constructed as the two side walls 54 of the movable heat sink 5″, and each side wall 54 is formed with a first recessed groove 548 and a second recessed groove 549 which is positioned in front of the first recessed groove. The first holding portions 542 are front ends of the first recessed grooves 548 constructed on the two side walls 54 of the movable heat sink 5″, the second holding portions 543 are rear ends of the second recessed grooves 549 constructed on the two side walls 54 of the movable heat sink 5″. The limiting pieces 127 of the two side walls 12 of the guiding shield cage 1 enter into the first recessed grooves 548 respectively.

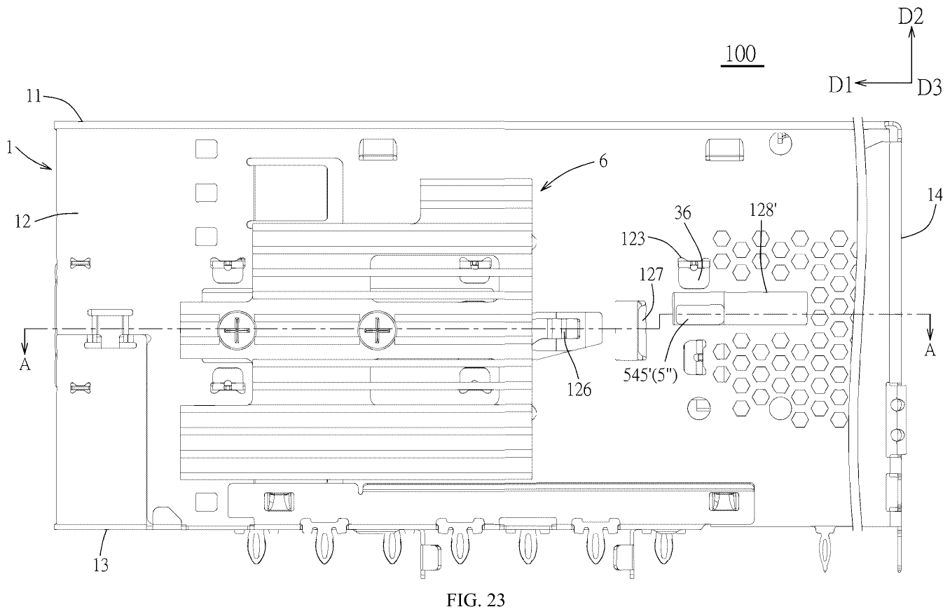

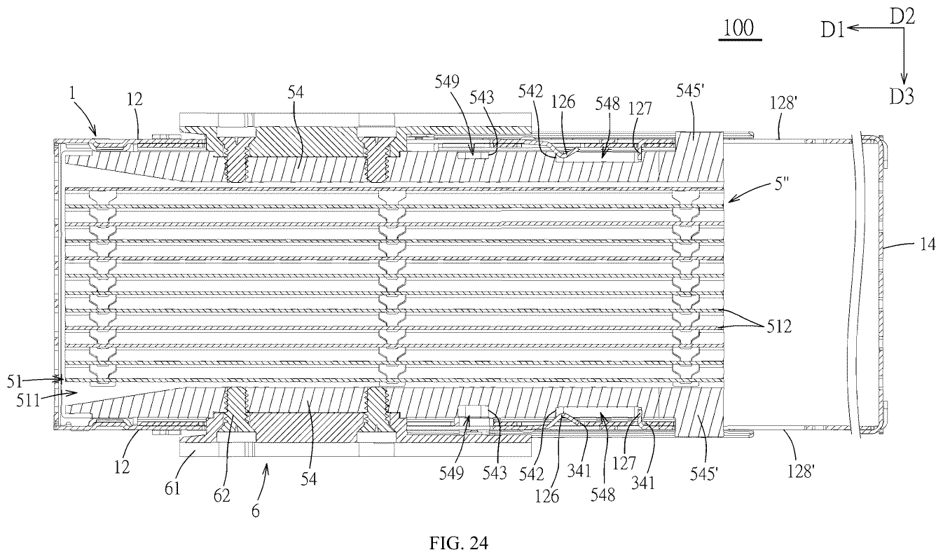

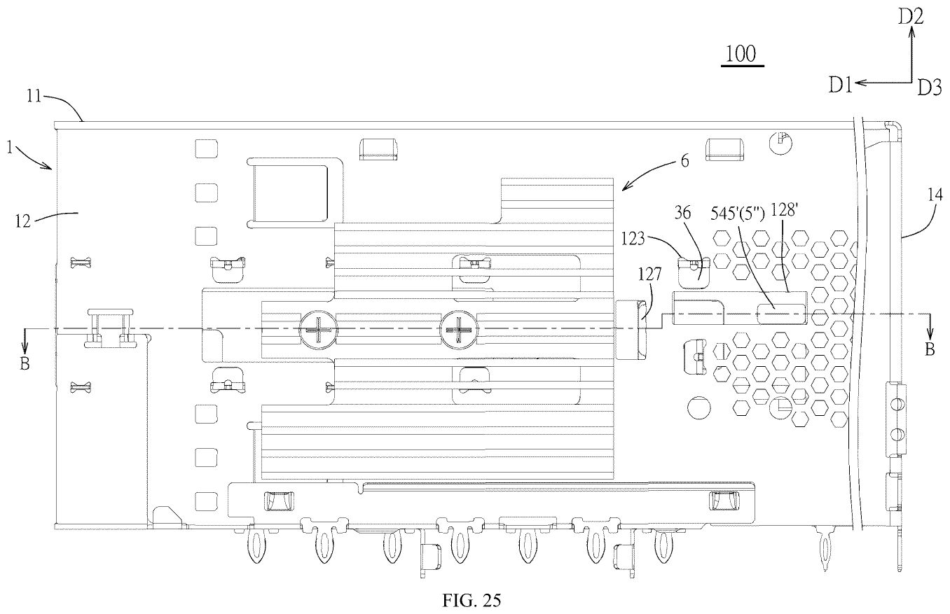

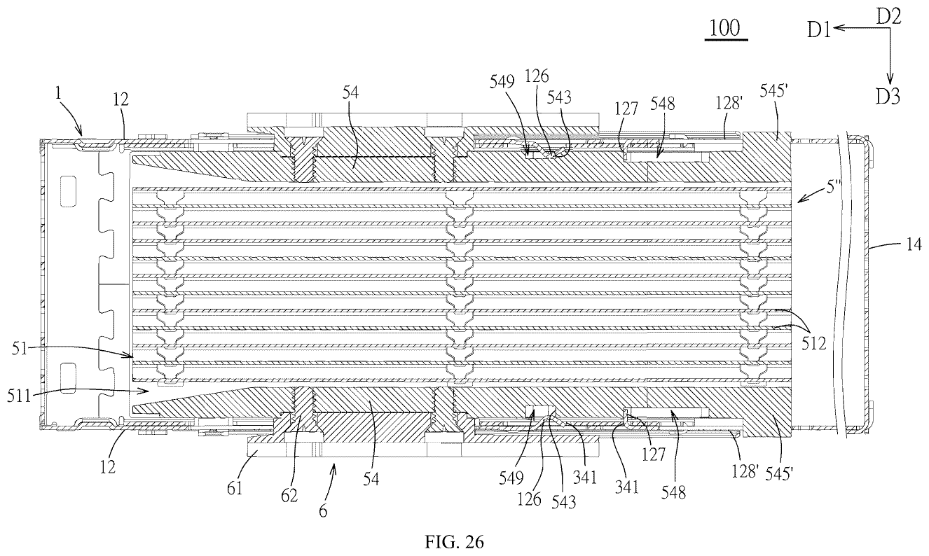

Referring to FIG. 21, FIG. 23 and FIG. 24, when the movable heat sink 5″ is positioned in the front position, the elastic holding piece (the holding member 126) latches with the front end of the first recessed groove 548 (the first holding portion 542), the limiting piece 127 positioned to the rear end of the first recessed groove 548; referring to FIG. 22, FIG. 25 and FIG. 26, when the movable heat sink 5″ is positioned in the rearward position, the elastic holding piece (the holding member 126) latches with the rear end of the second recessed groove 549 (the second holding portion 543), the limiting piece 127 is positioned to the front end of the first recessed groove 548.

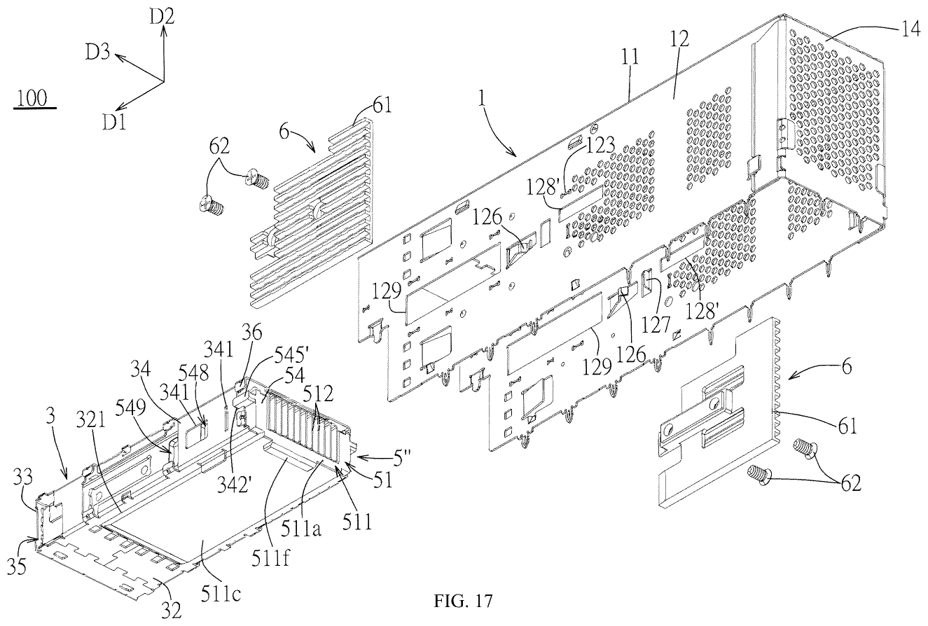

Referring to FIG. 16 and FIG. 17, moreover, in the third embodiment, the two side heat sinks 6 are provided to the two side walls 54 of the movable heat dissipating member 51 of the movable heat sink 5″ respectively from outer sides of the two side walls 12 of the guiding shield cage 1 by means of the two side wall openings 129, and the two side heat sinks 6 can move together with the movable heat sink 5″. Each side heat sink 6 includes a side heat dissipating member 61 and two screwing members 62 which fix the side heat dissipating member 61 to two screwing holes of the corresponding side wall 54, the two side heat sinks 6 can synergize with the movable heat dissipating member 51 of the movable heat sink 5″ for heat dissipating, so as to enhance heat dissipating efficiency.

In conclusion, in the present disclosure, by the movable heat sink 5, 5′, 5″ which is assembled in the partitioning bracket 3 and can move to the front position where the movable heat sink 5, 5′, 5″ is positioned in front of the upper receptacle 211 and the lower receptacle 212, the partitioning bracket 3 and the movable heat sink 5, 5′, 5″ do not interfere with the receptacle connector 2 when the partitioning bracket 3 and the movable heat sink 5, 5′, 5″ are assembled. After the assembling is completed, the movable heat sink 5, 5′, 5″ is moved rearwardly to the rearward position where the movable heat sink 5, 5′, 5″ enters into between the upper receptacle 211 and the lower receptacle 212 of the receptacle connector 2, by that the movable heat sink 5, 5′, 5″ moves toward the receptacle connector 2, a distance for heat dissipating function can be lengthened and a range where heat dissipating is performed is enlarged, in turn heat dissipating efficacy is promoted.

However, what is described above is just the embodiments of the present disclosure, which is not intended to limit the scope implementing the present disclosure, any simple equivalent variations and modifications made according to the claims and the specification of the present disclosure will also be fallen within the scope of the present disclosure.

What is claimed is:

1. A shield cage assembly, comprising:
a guiding shield cage comprising a limiting piece on a side wall;
a partitioning bracket provided in the guiding shield cage; and
a movable heat sink assembled to the partitioning bracket, the movable heat sink comprising a limiting groove in a side wall of the movable heat sink, wherein the movable heat sink is capable of moving relative to the partitioning bracket between a front position where the limiting piece is positioned at a rear end of the limiting groove and a rearward position where the limiting piece is positioned at a front end of the limiting groove.

2. The shield cage assembly of claim 1, wherein:
the side wall of the guiding shield cage further comprises an elastic holding piece, and
a side wall of the partitioning bracket comprises an avoiding opening which allows the elastic holding piece to pass through.

3. The shield cage assembly of claim 1, wherein:
the side wall of the guiding shield cage further comprises a holding member,
the movable heat sink further comprises a first holding portion on the side wall of the movable heat sink and a second holding portion on the side wall of the movable heat sink,
the holding member of the side wall of the guide shielding cage latches with the first holding portion when the movable heat sink is in the front position, and
the holding member of the side wall of the guide shielding cage latches with the second holding portion when the movable heat sink is in the rearward position.

4. The shield cage assembly of claim 1, wherein:
the movable heat sink comprises a movable heat dissipating member and a movable pressure-applying spring; and
the movable pressure-applying spring comprises a spring piece which presses against a wall of the partitioning bracket.

5. The shield cage assembly of claim 1, wherein:
the movable heat sink further comprises a guiding member,
the guiding shield cage further comprises a guiding rail groove, and
the guiding member is provided to the guiding rail groove such that the guiding member slides forwardly or rearwardly along the guiding rail groove.

6. The shield cage assembly of claim 5, wherein:
the partitioning bracket further comprises a receiving notch provided on a side wall of the partitioning bracket, and
when the movable heat sink is positioned in the front position, the guiding member of the movable heat sink is received in the receiving notch of the partitioning bracket.

7. The shield cage assembly of claim 1, further comprising an internal heat sink provided in a front segment of an internal receiving space of the partitioning bracket.

8. The shield cage assembly claim 1, wherein:
the movable heat sink further comprises a lower stopping portion which enters into a lower receiving space of the guiding shield cage, and
when the movable heat sink is in the front position, a pluggable module inserted into the lower receiving space pushes the movable heat sink to the rearward position.

9. The shield cage assembly of claim 1, further comprising side heat sinks, wherein the side heat sinks are positioned to outer sides of two side walls of the guiding shield cage respectively and move together with the movable heat sink.

10. A shield cage assembly, comprising:
a guiding shield cage comprising a holding member on a side wall; and
a movable heat sink comprising a first holding portion on a side wall of the movable heat sink and a second holding portion on the side wall of the movable heat sink, wherein:
the holding member of the side wall of the guide shielding cage latches with the first holding portion when the movable heat sink is in a front position, and
the holding member of the side wall of the guide shielding cage latches with the second holding portion when the movable heat sink is in a rearward position.

11. The shield cage assembly of claim 10, further comprising:
a partitioning bracket provided in the guiding shield cage; and
an internal heat sink provided in a front segment of an internal receiving space of the partitioning bracket, wherein the movable heat sink is assembled to the partitioning bracket.

12. The shield cage assembly of claim 11, wherein:
the side wall of the guiding shield cage further comprises an elastic holding piece, and
a side wall of the partitioning bracket comprises an avoiding opening which allows the elastic holding piece to pass through.

13. The shield cage assembly of claim 10, wherein:
the side wall of the guiding shield cage further comprises a limiting piece,
the movable heat sink further comprises a limiting groove in the side wall of the movable heat sink,
the limiting piece is positioned at a rear end of the limiting groove when the movable heat sink is in the front position, and
the limiting piece is positioned at a front end of the limiting groove when the movable heat sink is in the rearward position.

14. The shield cage assembly of claim 10, further comprising:
a partitioning bracket provided in the guiding shield cage, wherein:
the movable heat sink comprises a movable heat dissipating member and a movable pressure-applying spring; and
the movable pressure-applying spring comprises a spring piece which presses against a wall of the partitioning bracket.

15. The shield cage assembly of claim 10, wherein:
the movable heat sink further comprises a guiding member,
the guiding shield cage further comprises a guiding rail groove, and
the guiding member is provided to the guiding rail groove such that the guiding member slides forwardly or rearwardly along the guiding rail groove.

16. The shield cage assembly of claim 15, further comprising:
a partitioning bracket provided in the guiding shield cage, the partitioning bracket comprising a receiving notch, wherein, when the movable heat sink is positioned in the front position, the guiding member of the movable heat sink is received in the receiving notch of the partitioning bracket.

17. A connector assembly, comprising:
a guiding shield cage;
a receptacle connector provided within the guiding shield cage;
a partitioning bracket provided in the guiding shield cage; and
a movable heat sink assembled to the partitioning bracket, the movable heat sink comprising a lower stopping portion which enters into a lower receiving space of the guiding shield cage, wherein when the movable heat sink is in a front position, a pluggable module inserted into the lower receiving space pushes the movable heat sink to a rearward position.

18. The connector assembly according to claim 17, wherein the movable heat sink is positioned in front of the receptacle connector in the front position, and the movable heat sink at least partially enters into a space between an upper receptacle and a lower receptacle of the receptacle connector in the rearward position.

19. The connector assembly according to claim 17, wherein:
a side wall of the guiding shield cage comprises a holding member,
the movable heat sink further comprises a first holding portion on a side wall of the movable heat sink and a second holding portion on the side wall of the movable heat sink,
the holding member of the side wall of the guide shielding cage latches with the first holding portion when the movable heat sink is in the front position, and
the holding member of the side wall of the guide shielding cage latches with the second holding portion when the movable heat sink is in the rearward position.

20. The connector assembly according to claim 17, wherein:
the movable heat sink further comprises a guiding member,
the guiding shield cage further comprises a guiding rail groove, and
the guiding member is provided to the guiding rail groove such that the guiding member slides forwardly or rearwardly along the guiding rail groove.
